(19) United States
(12) Patent Application Publication
(10) Pub. No.: US 2020/0126817 A1
(43) Pub. Date: Apr. 23, 2020

(54) SUBSTRATE PROCESSING APPARATUS AND SUBSTRATE PROCESSING METHOD

(71) Applicant: TOKYO ELECTRON LIMITED, Tokyo (JP)

(72) Inventor: Hitoshi KOSUGI, Koshi City (JP)

(21) Appl. No.: 16/654,149

(22) Filed: Oct. 16, 2019

(30) Foreign Application Priority Data
Oct. 18, 2018 (JP) 2018197022

(51) Int. Cl. H01L 21/67; H01L 21/02; B08B 5/02; B08B 3/04

(52) U.S. Cl. CPC H01L 21/6715; B08B 3/041; B08B 5/023; H01L 21/02057

(57) ABSTRACT

A substrate processing apparatus includes: a substrate holding/rotating part configured to hold and rotate a substrate; a processing liquid supply nozzle configured to supply a processing liquid to a peripheral edge portion of the substrate held by the substrate holding/rotating part; and a gas supply nozzle provided inside the peripheral edge portion in a plan view and configured to supply a gas in an annular shape to a processing surface of the substrate to which the processing liquid is supplied, wherein the gas supply nozzle supplies the gas from a direction perpendicular to the processing surface toward a direction inclined outward from a rotation center of the substrate.

### CROSS-REFERENCE TO RELATED APPLICATION

This application is based upon and claims the benefit of priority from Japanese Patent Application No. 2018-197022, filed on Oct. 18, 2018, the entire contents of which are incorporated herein by reference.

### TECHNICAL FIELD

The present disclosure relates to a substrate processing apparatus and a substrate processing method.

### BACKGROUND

A semiconductor device manufacturing process includes a peripheral edge portion cleaning process for removing an unnecessary film or a contaminant on a peripheral edge portion of a semiconductor wafer (hereinafter, simply referred to as a “wafer”) as a substrate to be processed by supplying a processing liquid such as a chemical liquid to the peripheral edge portion of the wafer while rotating the wafer. Such cleaning is called bevel cleaning or edge cleaning.

Patent Document 1 discloses a substrate processing apparatus for performing the peripheral edge portion cleaning process. The substrate processing apparatus includes a spin chuck that holds and rotates a wafer in a horizontal posture, a processing liquid nozzle that supplies a processing liquid to the peripheral edge portion of the rotating wafer, a cup body that surrounds the wafer and collects the processing liquid scattered outward from the wafer, and a annular cover member. The cover member is located in proximity to the peripheral edge portion of the upper surface of the wafer, and covers the peripheral edge portion from above. The central portion of the wafer, which is located radially inside the peripheral edge portion, is exposed without being covered by the cover member. An internal space of the cup body is evacuated through an exhaust port provided in a lower portion of the cup body. At this time, a gas above the wafer (e.g., clean air) passes through a gap between a lower surface of the cover member and an upper surface of the peripheral edge portion of the wafer toward the outside of the wafer and flows into the internal space of the cup body.

According to the above configuration, a mist of the processing liquid is entrained into the gas passing through the gap between the lower surface of the cover member and the upper surface of the peripheral edge portion of the wafer toward the outside of the wafer, and flows into the internal space of the cup body. Therefore, it is possible to suppress formation of particles due to the mist of the processing liquid, drifting near the peripheral edge portion of the upper surface of the wafer and readhering to the wafer. The mist of the processing liquid may be formed when the processing liquid is ejected from a nozzle having a small diameter, or may be formed when the processing liquid, ejected from the nozzle, collides with the peripheral edge portion of the upper surface of the wafer and rebounds.

### PRIOR ART DOCUMENT

### Patent Document

Patent Document 1: Japanese Laid-Open Patent Publication No. 2014-086639

### SUMMARY

According to an embodiment of the present disclosure, there is provided a substrate processing apparatus, which includes: a substrate holding/rotating part configured to hold and rotate a substrate; a processing liquid supply nozzle configured to supply a processing liquid to a peripheral edge portion of the substrate held by the substrate holding/rotating part; and a gas supply nozzle provided inside the peripheral edge portion in a plan view and configured to supply a gas in an annular shape to a processing surface of the substrate to which the processing liquid is supplied, wherein the gas supply nozzle is further configured to supply the gas in the annular shape or to a vicinity of the processing liquid supply nozzle from a direction perpendicular to the processing surface toward a direction inclined outward from a rotation center of the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view illustrating a liquid processing apparatus according to an embodiment of the present disclosure.

FIG. 2 is a plan view illustrating a gas supply nozzle, a lifting mechanism thereof, and a processing liquid supply part of a liquid processing apparatus according to an embodiment of the present disclosure.

FIG. 3 is a vertical cross-sectional view illustrating in detail a region near an outer peripheral edge portion of the left wafer in FIG. 1 on an enlarged scale.

FIG. 4 is a cross-sectional view illustrating an exemplary configuration of a gas supply nozzle.

FIG. 5 is a schematic view illustrating an operation of a gas supply nozzle.

FIG. 6 is a plan view illustrating exemplary air flow from a gas supply nozzle.

FIG. 7 is a schematic view illustrating a behavior of mist in an embodiment of the present disclosure.

FIGS. 8A and 8B are schematic views illustrating an operation of a lifting mechanism.

FIG. 9 is a flowchart illustrating exemplary processing executed in a liquid processing apparatus.

FIG. 10 is a cross-sectional view illustrating another exemplary configuration of a gas supply nozzle.

FIGS. 11A and 11B are plan views illustrating other exemplary air flow from a gas supply nozzle.

FIG. 12 is a plan view illustrating another exemplary gas supply nozzle, a lifting mechanism thereof, and a processing liquid supply part of the liquid processing apparatus according to an embodiment of the present disclosure.

FIG. 13 is a plan view showing another exemplary air flow from a gas supply nozzle.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a liquid processing apparatus 1 as an embodiment of a substrate processing apparatus of the present disclosure will be described with reference to the accompanying drawings. The liquid processing apparatus 1 removes an unnecessary film formed on a peripheral edge portion of a surface of a semiconductor wafer W, which is a circular substrate on which a semiconductor device is formed, and removes a contaminant from the peripheral edge portion by supplying a chemical liquid to the peripheral edge portion of the surface of the semiconductor wafer W. In addition, in the specification and drawings, constituent elements having substantially the same functional configurations may be denoted by the same reference numerals and redundant descriptions may be omitted. In the present disclosure, the term “annular shape” does not strictly mean that it is continuous in the entire circumferential direction, and also includes a shape in which a chipped portion exists in a portion thereof in the circumferential direction to the extent that a certain effect can be obtained.

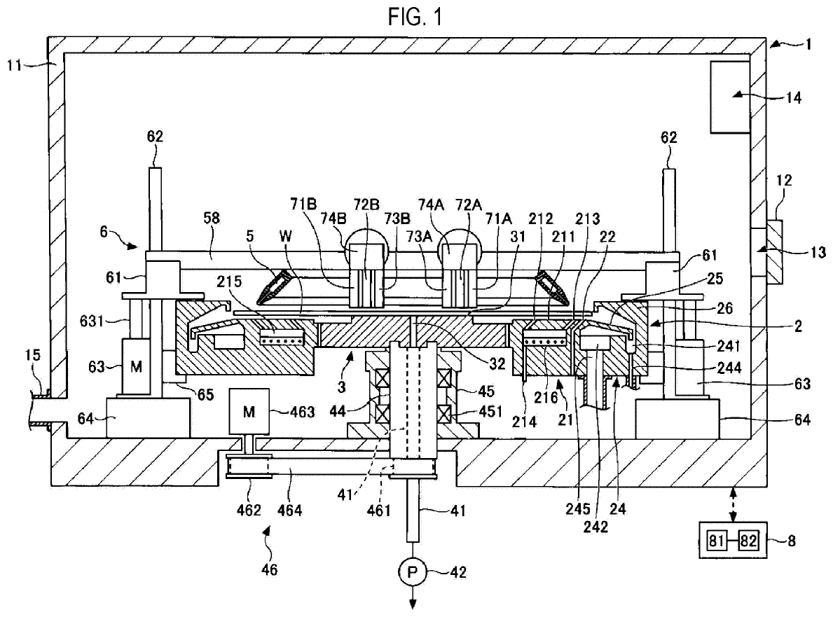

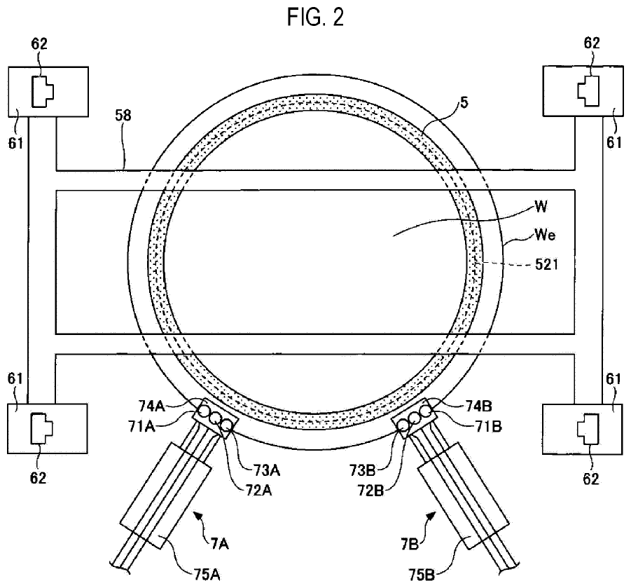

As illustrated in FIGS. 1 and 2, the liquid processing apparatus 1 includes a wafer holder 3, which holds a wafer W in a horizontal posture to be rotatable about a vertical axis, and a cup body 2, which surrounds the periphery of the wafer W held by the wafer holder 3 and receives the processing liquid scattered from the wafer W. The liquid processing apparatus 1 further includes a gas supply nozzle 5 that supplies a gas to an upper surface of the wafer W held by the wafer holder 3, a lifting mechanism 6 that raises and lowers the gas supply nozzle 5, and processing fluid supply parts 7A and 7B that supplies a processing fluid to the wafer W held by the wafer holder 3. The lifting mechanism 6 is an example of a movement mechanism.

The cup body 2, the wafer holder 3, the gas supply nozzle 5, and the like, which are constituent members of the liquid processing apparatus 1 described above, are accommodated in a single housing (chamber) 11. A clean air introduction unit (fan filter unit) 14, which introduces clean gas (clean air in the illustrated example) from the outside is provided near a ceiling part of the housing 11 (in the illustrated example, in an upper portion of a side wall of the housing 11). An exhaust port (housing exhaust port) 15, which exhausts—an atmosphere in the housing 11 is provided near a bottom surface of the housing 11. The clean air introduction unit 14 may be provided in a central portion of the ceiling wall of the housing 11. The clean gas may be a gas such as clean dry air and nitrogen gas in addition to clean air (clean air). A loading/unloading port 13 that is opened/closed by a shutter 12 is provided in one side wall of the housing 11. A transport arm of a wafer transport mechanism (not illustrated) provided outside the housing 11 is capable of passing through the loading/unloading port 13 in the state of holding the wafer W.

The wafer holder 3 is configured as a disk-shaped vacuum chuck, and has a wafer suction surface 31 formed in an upper surface thereof. A suction port 32 opens in the central portion of the wafer suction surface 31. A hollow cylindrical rotary shaft 44 extends in the vertical direction in a central portion of a lower surface of the wafer holder 3. A suction conduit 41 connected to the suction port 32 passes through an internal space of the rotary shaft 44. The suction conduit 41 is connected to the vacuum pump 42 outside the housing 11. By driving the vacuum pump 42, the wafer W is capable of being sucked and held by the wafer holder 3.

The rotary shaft 44 is supported by a bearing casing 45 including therein a bearing 451, and the bearing casing 45 is supported by the bottom surface of the housing 11. The rotary shaft 44 may be rotated at a desired speed by a rotary driving mechanism 46 including a driven pulley 461 on the rotary shaft 44, a driving pulley 462 on a rotary shaft of a driving motor 463, and a driving belt 464 spanned between the driven pulley 461 and the driving pulley 462. A substrate holding/rotating part is formed by the wafer holder 3, the rotary shaft 44, the rotary driving mechanism 46, and the like.

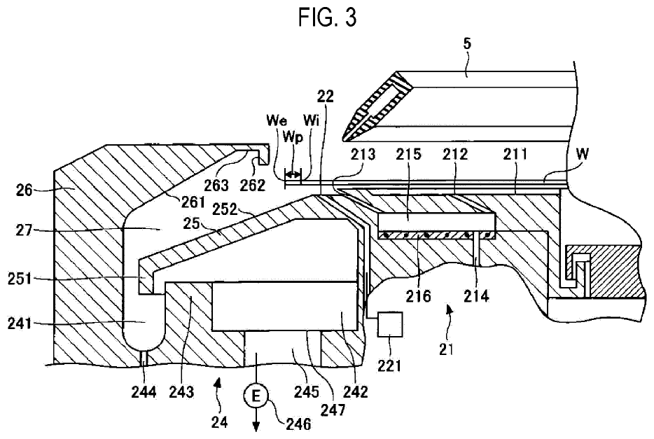

As illustrated in FIG. 3, the cup body 2 is a bottomed annular member provided so as to surround the outer periphery of the wafer holder 3. The cup body 2 has functions of receiving and collecting the chemical liquid that is supplied to the wafer W and is then scattered outward from the wafer W, and discharging the collected chemical liquid outside the liquid processing apparatus 1.

A relatively small gap is formed between a lower surface of the wafer W held by the wafer holder 3 and an upper surface 211 of an inner peripheral portion 21 of the cup body 2 facing the lower surface of the wafer W. A height of the gap is, for example, about 2 mm to 3 mm Two gas ejection ports 212 and 213 open in the upper surface 211 facing the wafer W. These two gas ejection ports 212 and 213 continuously extend along concentric large-diameter and small-diameter circumferences, respectively, and eject hot N₂ gas (heated nitrogen gas) radially outward and obliquely upward toward the lower surface of the wafer W. Specifically, N₂ gas of ordinary temperature is supplied from a gas introduction line 214 to an annular gas diffusion space 215, and when flowing in the gas diffusion space 215, the N₂ gas of ordinary temperature is heated by a heater 216 to become hot N₂ gas, which is ejected from the gas ejection ports 212 and 213. This hot N₂ gas promotes a reaction of the chemical liquid by heating the peripheral edge portion of the wafer W, which is a portion to be processed in the wafer W, and prevents the mist of the processing liquid, which is scattered after being ejected toward a surface (upper surface) of the wafer W, from entering a rear surface (lower surface) of the wafer.

Two top-opened annular recesses 241 and 242 are formed in an outer peripheral portion 24 of the cup body 2 along a circumferential direction of the cup body 2. The recesses 241 and 242 are partitioned by an annular separation wall 243. A drainage path 244 is connected to a bottom of the outer recess 241. In addition, an exhaust port (cup exhaust port) 247 is provided in a bottom of the inner recess 242, and an exhaust path 245 is connected to the exhaust port 247. An exhaust apparatus 246 such as an ejector or a vacuum pump is connected to the exhaust path 245. During the operation of the liquid processing apparatus 1, an internal space of the cup body 2 is always sucked through the exhaust path 245, and a pressure in the inner recess 242 is kept lower than a pressure in the housing 11 outside the cup body 2.

An annular guide plate 25 extends outward in the radial direction from the outer peripheral portion of the inner peripheral portion 21 of the cup body 2 (a position below the peripheral edge of the wafer W). The guide plate 25 is inclined so as to become lower toward the outer side in the radial direction. The guide plate 25 covers the entire inner recess 242 and an upper part of an inner peripheral side portion of the outer recess 241, and a tip portion 251 (radially outer peripheral edge portion) of the guide plate 25 is bent downward to protrude into the outer recess 241.

An outer peripheral wall 26, which is continuous with the outer wall surface of the outer recess 241, is provided on the outer peripheral portion of the outer peripheral portion 24 of the cup body 2. The outer peripheral wall 26 receives fluid (mist (liquid droplets) of a processing liquid, gas, and a mixture thereof) scattered outward from the wafer W by the inner peripheral surface thereof, and guides the fluid toward the outer recess 241. The outer peripheral wall 26 includes an inner fluid receiving surface 261, which is inclined so as to be lower toward the outer side in the radial direction at an angle of 25 to 30 degrees with respect to a horizontal plane, and a return portion 262 extending downward from the upper end portion of the fluid receiving surface 261. Between an upper surface 252 of the guide plate 25 and the fluid receiving surface 261, an exhaust flow path 27 is formed through which gas (e.g., air or N₂ gas) and the mist of the processing liquid scattered from the wafer W flow.

The mixed fluid of gas and mist that has flowed into the outer recess 241 through the exhaust flow path 27 flows between the guide plate 25 and the separation wall 243 and flows into the inner recess 242. When passing between the guide plate 25 and the separation wall 243, a flow direction of the mixed fluid suddenly turns, and the mist (droplets) contained in the mixed fluid collides with the tip portion 251 of the guide plate 25 or the separation wall 243, thereby being separated from the fluid. Then, the mist flows along the lower surface of the guide plate 25 or the surface of the separation wall 243 and into the outer recess 241 to be discharged from the drainage path 244. The fluid, from which the mist has been removed and which flowed into the inner recess 242, is discharged from the exhaust path 245.

As illustrated in FIG. 3, the gas supply nozzle 5 is disposed so as to face a portion inside the peripheral edge portion Wp of the wafer W held by the wafer holder 3 when the processing is executed. The gas supply nozzle 5 includes a gas storage part 51 and a slit part 52 mounted on the tip portion of the gas storage part 51. A slit 521 is formed in the slit part 52. For example, a width of the slit 521 is 1 mm or less, and the slit 521 is formed in an annular shape on the radially inner side from an inner peripheral end Wi of the peripheral edge portion Wp of the wafer W. In addition, the slit 521 is formed so as to face outward in the radial direction as it approaches the wafer W. Here, the “peripheral edge portion Wp of the wafer W” means an annular area in which no device is formed. The “inner peripheral edge Wi of the peripheral edge portion Wp of the wafer W” is a circumscribed circle of a device forming area having its center on the center of the wafer W, that is, a circle centered on the center of the wafer W and having a minimum radius determined such that the device forming area is not included outside the circle. A radial width of the peripheral edge portion Wp of the wafer W, that is, the radial distance from an outer peripheral end We of the wafer W to the inner peripheral edge Wi of the peripheral edge portion Wp of the wafer W is, for example, about 1 mm to 3 mm. As will be described in detail later, the slit part 52 supplies the gas supplied from the outside through the gas storage part 51 to a portion inside the peripheral edge portion Wp of the wafer W in an annular shape, and prevents the processing liquid scattered from the wafer W on the upper surface of the wafer W from adhering to the wafer W again. The flow rate of the gas ejected from the slit part 52 is, for example, 50 L/min to 500 L/min. For example, air may be used as the gas. Although not illustrated, for example, an unnecessary film to be removed such as an oxide film is formed on the peripheral edge portion Wp of the wafer W.

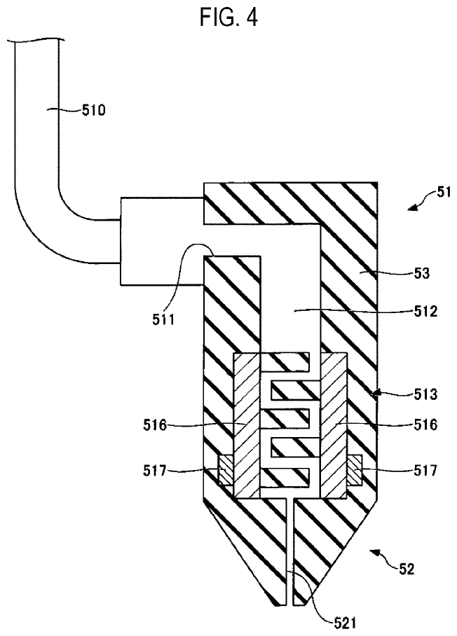

As illustrated in FIG. 4, the gas storage part 51 and the slit part 52 are formed integrally with a ceramic housing 53. The gas storage part 51 is provided with a supply port 511 to which gas is supplied from an air supply line 510, an air buffer chamber 512 connected to the supply port 511, and a heat exchanger 513 connected to the air buffer chamber 512. The heat exchanger 513 includes a heater 516 and a temperature sensor 517 that detects a temperature of the heater 516. Inside the heat exchanger 513, a gas flow path is formed so as to narrowly meander inside the heater 516. For example, a height of the slit part 52 is 5 mm to 15 mm, a height of the gas storage part 51 is 25 mm to 35 mm, and a width of the gas storage part 51 is 10 mm to 20 mm.

The gas supplied from the air supply line 510 is supplied to the heat exchanger 513 through the air buffer chamber 512, heated by the heater 516 in the heat exchanger 513, and ejected from the slit 521. The temperature of the heater 516 is detected by the temperature sensor 517, and the gas temperature is adjusted. The air supply line 510 is connected, for example, to a compressed gas supply source, and an opening/closing valve, a flow rate adjustment valve, and the like are provided on the air supply line. The supply source, the opening/closing valve, the flow rate adjustment valve, and the like are included in a gas flow rate control mechanism.

As illustrated in FIGS. 1 and 2, the lifting mechanism 6, which raises and lowers the gas supply nozzle 5 includes a plurality of (four in this example) sliders 61 attached to a support 58 that supports the gas supply nozzle 5, and guide columns 62 extending through the sliders 61 in the vertical direction, respectively. Each slider 61 is connected to a linear actuator, for example, a rod 631 of a cylinder motor 63. By driving the cylinder motor 63, the sliders 61 move up and down along the guide columns 62, whereby the gas supply nozzle 5 is capable of being raised and lowered. The cup body 2 is supported by a lifter 65 that forms a part of a cup lifting mechanism (not illustrated in detail). When the lifter 65 is lowered from the state illustrated in FIG. 1, the cup body 2 is lowered, and wafer W delivery is enabled between a transport arm (not illustrated) of a wafer transport mechanism and the wafer holder 3. The guide columns 62 are supported by bases 64 supported on, for example, the floor surface of the housing 11.

Next, the processing fluid supply parts 7A and 7B will be described with reference to FIGS. 1 and 2. The processing fluid supply part 7A includes a chemical liquid nozzle 71A that ejects a chemical liquid (HF in this example), a rinse nozzle 72A that ejects a rinsing liquid (DIW (pure water) in this example), and a gas nozzle 73A that ejects a drying gas (N₂ gas in this example). The chemical liquid nozzle 71A, the rinse nozzle 72A, and the gas nozzle 73A are mounted on a common nozzle holder 74A. The nozzle holder 74A is mounted on a linear actuator 75A, for example, a cylinder motor. By driving the linear actuator 75A, supply positions of the processing fluid from the nozzles 71A to 73A onto the wafer W may be moved in the radial direction of the wafer W.

As illustrated in FIG. 2, the nozzles 71A to 73A are provided outside the gas supply nozzle 5 in the radial direction of the wafer W. The processing fluid is supplied to each of the nozzles 71A to 73A from a processing fluid supply mechanism (not illustrated) connected thereto. Each processing fluid supply mechanism may include a processing fluid supply source such as a tank, a conduit that supplies the processing fluid from the processing fluid supply source to the nozzle, and flow control devices such as an opening/closing valve and a flow rate adjustment valve provided in the conduit.

The processing fluid supply part 7B includes substantially the same components as the processing fluid supply part 7A, that is, a chemical liquid nozzle 71B, a rinse nozzle 72B, a gas nozzle 73B, and a nozzle holder 74B. The nozzles 71B to 73B are also provided outside the gas supply nozzle 5 in the radial direction of the wafer W. Like the nozzle holder 74A, the nozzle holder 74B is capable of being moved in the radial direction of the wafer by the linear actuator 75B. An arrangement order of the nozzles 71B to 73B in the circumferential direction of the wafer W is opposite that of the nozzles 71A to 73A. In addition, the processing fluid is ejected from each of the nozzles 71B to 73B such that an ejection direction has a component in the reverse rotation direction of the wafer. That is, in brief, the processing fluid supply part 7B has a configuration in which the processing fluid supply part 7A is substantially mirror-inverted. In the present embodiment, an acidic chemical liquid is supplied from the chemical liquid nozzle 71A, and an alkaline chemical liquid is supplied from the chemical liquid nozzle 71B. The chemical liquids and the rinsing liquid are examples of processing liquids, and the nozzles 71A, 71B, 72A, and 72B are examples of processing liquid supply nozzles.

In addition, as illustrated in FIG. 3, in the inner peripheral portion 21 of the cup body 2, on the further outer side of the gas ejection port 213, a plurality of processing liquid ejection ports 22 (only one is illustrated in the drawing) are formed at different positions in the circumferential direction. Each processing liquid ejection port 22 ejects the processing liquid toward the outer peripheral edge portion of the lower surface of the wafer, toward the outside of the wafer W, and obliquely upward. From at least one of the plurality of processing liquid ejection ports 22, a chemical liquid, which is the same as the chemical liquid ejected from the chemical liquid nozzle 71A, may be ejected. From at least one of other processing liquid ejection ports 22, a chemical liquid, which is the same as the chemical liquid ejected from the chemical liquid nozzle 71B, may be ejected. From at least one of other processing liquid ejection ports 22, a rinse liquid, which is the same as the rinse liquid ejected from the rinse nozzles 72A and 72B, may be ejected. A processing fluid supply mechanism (not illustrated) similar to each of the nozzles 71A, 71B, 72A, and 72B is connected to each processing liquid ejection port 22.

As schematically illustrated in FIG. 1, the liquid processing apparatus 1 includes a controller (control part) 8 that performs overall control of the entire operation. The controller 8 controls the operation of all the functional components of the liquid processing apparatus 1 (e.g., the rotary driving mechanism 46, the lifting mechanism 6, the vacuum pump 42, and various processing fluid supply mechanisms). The controller 8 may be realized by, for example, a general-purpose computer as hardware and a program (e.g., an apparatus control program or a processing recipe) for operating the computer as software. The software is stored in a storage medium such as a hard disk drive fixedly provided in the computer, or is stored in a storage medium that is detachably set in the computer, such as a CD-ROM, DVD, or flash memory. Such a storage medium is denoted by reference numeral 81 in FIG. 1. The processor 82 calls and executes a predetermined processing recipe from the storage medium 81 based on an instruction from a user interface (not illustrated) or the like as required, whereby each functional component of the liquid processing apparatus 1 operates under the control of the controller 8 to perform predetermined processing.

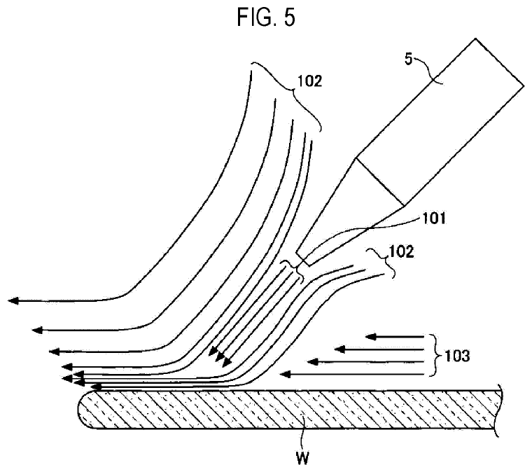

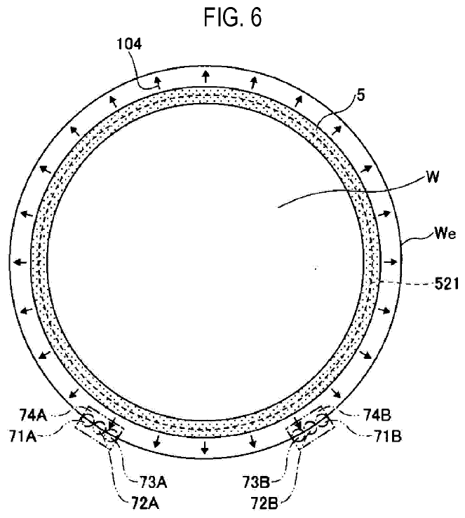

Here, the operation of the gas supply nozzle 5 will be described with reference to FIGS. 5 to 7. As described above, the slit 521 is formed to face radially outwards as approaching the wafer W located radially inside the inner peripheral end Wi of the peripheral edge portion Wp of the wafer W. Accordingly, as illustrated in FIG. 5, the gas ejected from the slit 521 travels in a direction in which the direction perpendicular to the upper surface of the wafer W and the direction outward in the radial direction are combined. At this time, the air flow 101 of the ejected gas itself is formed. In addition, when such air flow 101 is formed, air around the air flow 101 is entrained by a Coanda effect, and air flow 102 is formed by the Coanda effect. In particular, when air is ejected at a flow rate of, for example, about 50 L/min to 500 L/min, it is possible to form a large air flow 102. The Coanda effect is a phenomenon that occurs when a jet draws in surrounding fluid due to the effect of viscosity. In addition, swirling air flow 103 formed by the rotation of the wafer W is also formed. The air flows 101, 102, and 103 are all directed outward in the radial direction of the wafer W along the upper surface of the wafer W. Therefore, as illustrated in FIG. 6, on the upper surface of the peripheral edge portion Wp of the wafer W, strong air flow 104, which is obtained by combining the air flows 101, 102, and 103 and is directed outward in the radial direction of the wafer W, is formed. In this way, the gas supply nozzle 5 is capable of forming an air curtain.

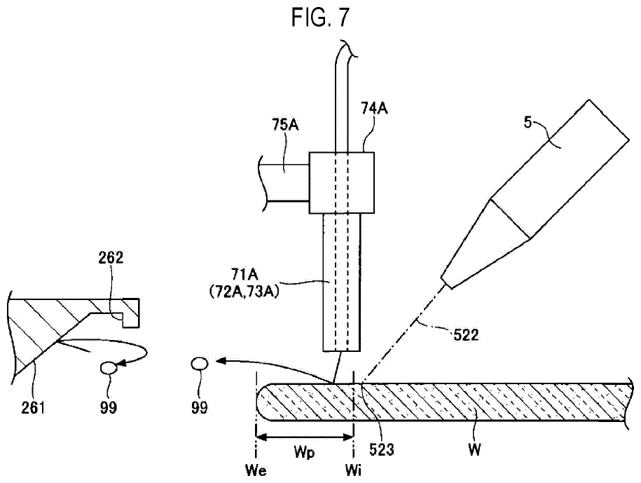

Accordingly, as illustrated in FIG. 7, by setting a position at which an extension line 522 of the slit 521 intersects the upper surface of the wafer W (a grounding position 523 at which the air flow 101 is in contact with the wafer W) to be located at the inner peripheral edge Wi or the inside thereof, it is possible to continuously discharge the mist 99 scattered at the peripheral edge portion Wp to the outside of the wafer W. In addition, some of the mist 99 discharged to the outside may rebound from the fluid receiving surface 261. However, the rebounding mist 99 is entrained in the air curtain before reaching the wafer W and is re-emitted to the outside. Accordingly, it is possible to remarkably reduce the readhesion of the mist 99 of the chemical liquid or the rinse liquid to the wafer W, and to reliably suppress the formation of particles. For example, the distance between the inner peripheral end Wi of the peripheral edge portion Wp and the grounding position 523 of the air flow 101 is set to 2 mm or less. Although it depends on the wafer W, since the width of the peripheral edge portion Wp is generally 1 mm to 3 mm, the distance between the outer peripheral end We of the wafer W and the grounding position 523 of the air flow 101 is set to, for example, 1 mm to 5 mm.

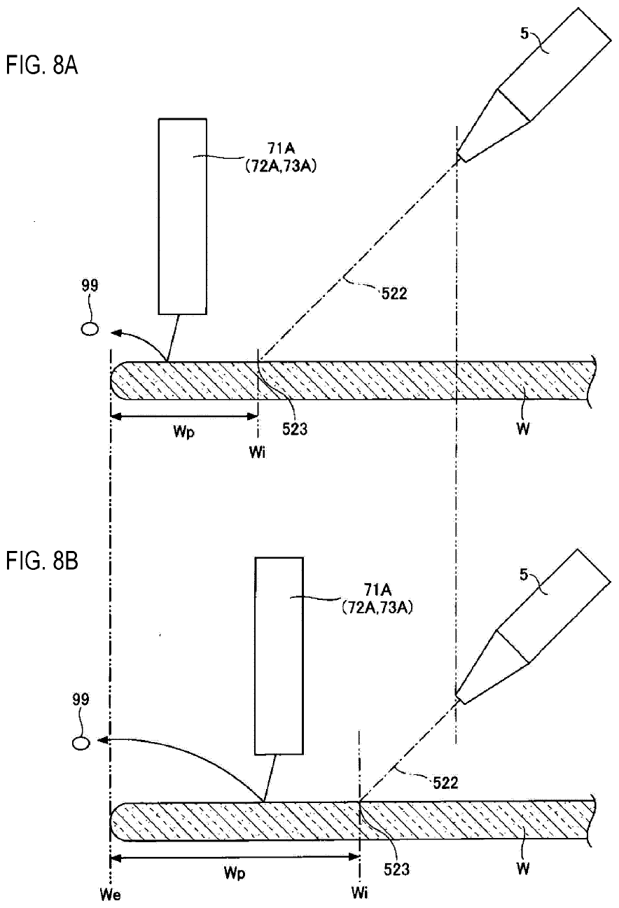

In addition, as illustrated in FIGS. 8A and 8B, it is possible to control the grounding position 523 by adjusting the height of the gas supply nozzle 5 from the upper surface of the wafer W using the lifting mechanism 6. Even if the sizes of wafers W are the same, the widths of the peripheral edges Wp may differ depending on the wafers W. For example, the width of the peripheral edge portion Wp in FIG. 8A is smaller than the width of the peripheral edge portion Wp in FIG. 8B. Even in such a case, since it is possible to adjust the grounding position 523 by adjusting the height of the gas supply nozzle 5, it is possible to appropriately control a distance between the inner peripheral edge Wi and the grounding position 523 while maintaining the positional relationship between the gas supply nozzle 5 and the wafer W in a plan view. In the example illustrated in FIGS. 8A and 8B, the distance between the inner peripheral edge Wi and the grounding position 523 is set to 0 mm, but this distance may be set to, for example, 2 mm or less.

For example, as will be described later, during the processing, the chemical liquid nozzles 71A and 71B may reciprocate in the radial direction of the wafer W within the range of the peripheral edge portion Wp. Even in such a case, by controlling the grounding position 523, it is possible to appropriately control the distance between the position where the chemical liquid reaches the wafer W and the grounding position 523, for example, to keep the distance constant.

The height of the lower end of the slit part 52 from the upper surface of the wafer W is not particularly limited, but the mist 99 of the chemical liquid and the rinse liquid may be directed to the slit part 52 through a path that the air flows 101, 102, and 103 do not reach. Accordingly, the height may be a height that makes it difficult for the mist 99 to reach the slit part 52 even when the mist 99 is formed in some embodiments. The height of the lower end of the slit part 52 from the upper surface of the wafer W is, for example, 5 mm to 10 mm, and the gas supply nozzle 5 may be driven in the vertical direction by the lifting mechanism 6 within this range in some embodiments. For example, the distance that the gas supply nozzle 5 is capable of being driven in the vertical direction is set to, for example 3 mm to 5 mm.

Since the processing using the chemical liquid is based on a chemical reaction, the temperature of the peripheral edge portion Wp may be kept high in order to improve the reaction efficiency in some embodiments. For this reason, the wafer W is heated by a wafer heating heater (not illustrated) provided in the wafer holder 3 or hot N₂ gas ejected from the gas ejection ports 212 and 213. For example, the temperature of the wafer W in the vicinity of the heater provided in the wafer holder 3 is about 90 degrees C. Meanwhile, the chemical liquid is supplied to the peripheral edge portion Wp at a temperature of 20 degrees C. to 25 degrees C., and the peripheral edge portion Wp is cooled by the heat of vaporization when the chemical liquid is evaporated. For this reason, the peripheral edge part Wp at the time of a chemical reaction is about 50 degrees C. Although it is conceivable to increase the output of the wafer heating heater or the heater 216, since the thermal conductivity of a wafer W of silicon or the like is generally not so high, it is difficult to sufficiently raise the temperature of the peripheral edge portion Wp even if the output of the wafer heating heater or the heater 216 is increased. In contrast, in this embodiment, the gas heated by the heater 516 in the gas supply nozzle 5 may be supplied from the slit part 52 to the peripheral edge portion Wp. Therefore, according to this embodiment, it is possible to directly and continuously heat the peripheral edge portion Wp in which a chemical reaction is to occur, and to easily maintain the peripheral edge portion Wp at a desired temperature. In addition, when the output of the wafer heating heater is increased, a temperature load is applied to surrounding parts and the like, and thus the parts may be easily deteriorated. However, when the gas heated by the heater 516 is used, it is possible to avoid such degradation.

Next, the operation of the liquid processing apparatus 1 performed under the control of the controller 8 will be described. The operation of the liquid processing apparatus 1 is an example of a substrate processing method.

### [Wafer Loading and Holding]

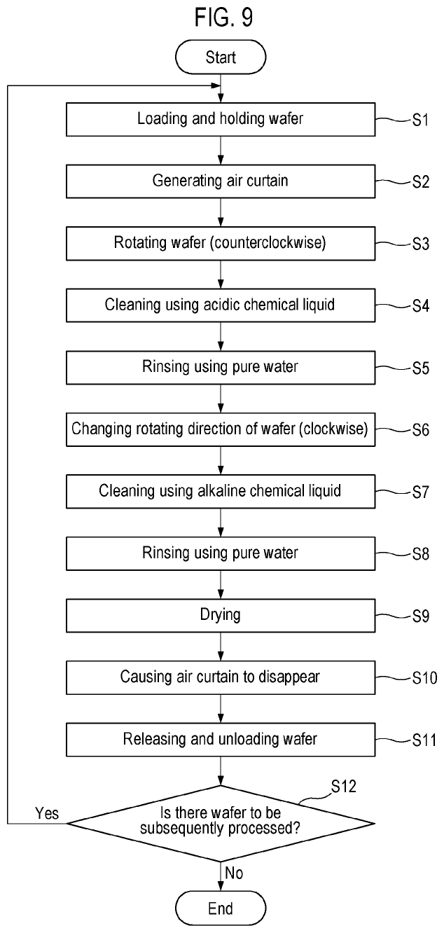

First, the gas supply nozzle 5 is positioned at a retracted position (a position above the position in FIG. 1 and near the upper end of the guide column 62) by the lifting mechanism 6, and the cup body 2 is lowered by the lifter 65 of the cup lifting mechanism. Next, the shutter 12 of the housing 11 is opened, a transport arm (not illustrated) of an external wafer transport mechanism (not illustrated) enters the housing 11, and the wafer W held by the transport arm is located directly above the wafer holder 3. Next, the transport arm is lowered to a position lower than the upper surface of the wafer holder 3, and the wafer W is placed on the upper surface of the wafer holder 3. Next, the wafer is sucked by the wafer holder 3. Thereafter, the empty transport arm is withdrawn from the housing 11. Next, the cup body 2 is raised and returned to the position illustrated in FIG. 1, and the gas supply nozzle 5 is lowered to the processing position illustrated in FIG. 1. According to the above procedure, the loading of the wafer W and the holding of the wafer W by the wafer holder 3 are completed, and the state illustrated in FIG. 1 is obtained (step S1 in FIG. 9).

### [Generation of Air Curtain]

Next, the gas supply nozzle 5 is operated to form an air curtain that flows on the upper surface of the peripheral edge portion Wp of the wafer W (step S2 in FIG. 9). Thereafter, the formation of the air curtain continues until the gas supply nozzle 5 is stopped.

### [First Chemical Liquid Processing Using Acidic Chemical Liquid]

Next, first liquid processing on a wafer is performed. The wafer W is rotated counterclockwise at a predetermined speed (step S3 in FIG. 9), and hot N₂ gas is ejected from the gas ejection ports 212 and 213 of the cup body 2 so that the wafer W, particularly the peripheral edge portion of the wafer W, which is an area to be processed, is heated to a temperature suitable for chemical processing. For example, the rotation speed of the wafer W is set to an appropriate rotation speed between 1500 rpm and 2500 rpm, and the temperature of the peripheral edge portion is set to an appropriate temperature between 60 degrees C. and 80 degrees C. In the case of performing chemical processing that does not require heating of the wafer W, N₂ gas having ordinary temperature may be ejected without operating the heater 216. When the wafer W is sufficiently heated, an acidic chemical liquid (e.g., hydrofluoric acid) is supplied from the chemical liquid nozzle 71A to the peripheral edge portion of the upper surface (a device forming surface) of the wafer W while the wafer W is being rotated, so as to remove an unnecessary film on the peripheral edge portion of the upper surface of the wafer. At the same time, a chemical liquid, which is the same as the chemical liquid supplied from the chemical liquid nozzle 71A, is supplied from the processing liquid ejection port 22 for chemical liquid to the peripheral edge portion of the wafer W so as to remove an unnecessary film on the peripheral edge portion of the lower surface of the wafer. The chemical liquid supplied to the upper and lower surfaces of the wafer W flows while spreading outward by centrifugal force, flows out of the wafer W together with the removed substance, and is collected by the cup body 2. When performing chemical liquid processing, the linear actuator 75A is driven as necessary to reciprocate the chemical nozzle 71A, which is ejecting the chemical liquid, in the radial direction of the wafer W, thereby improving processing uniformity. When the chemical liquid nozzle 71A reciprocates in the radial direction of the wafer W, it is possible to adjust the height of the gas supply nozzle 5 by the lifting mechanism 6 as described above, and to control a distance between the position at which the chemical liquid reaches the wafer W and the grounding position 523 of the air flow 101 (step S4 in FIG. 9).

### [First Rinse Processing]

After performing the chemical processing for a predetermined time, the wafer W is continuously rotated in the counterclockwise direction (the rotation speed may be changed) and the hot N₂ gas is continuously ejected from the gas ejection ports 212 and 213. Then, while continuing rotation and ejection, the ejection of the chemical liquid from the chemical liquid nozzle 71A and the processing liquid ejection port 22 for chemical liquid is stopped, and the rinse liquid (DIW) is supplied from the rinse nozzle 72A and the processing liquid ejection port 22 for rinse liquid to the peripheral edge portion of the wafer W so as to perform the rinse processing. By this rinse processing, the chemical liquid, a reaction product, and the like remaining on the upper and lower surfaces of the wafer W are washed away. From the viewpoint of preventing the wafer W from being cooled, the rinse liquid used in the first rinse processing may be hot DIW (heated DIW) (step S5 in FIG. 9) in some embodiments.

### [Second Chemical Liquid Processing Using Alkaline Chemical Liquid]

Next, second liquid processing is performed on the wafer. First, the rotation direction of the wafer W is reversed, and the wafer W is rotated clockwise at a predetermined speed (e.g., an appropriate rotation speed between 1500 rpm and 2500 rpm) (step S6 in FIG. 9). Subsequently, hot N₂ gas is ejected from the gas ejection ports 212 and 213 of the cup body 2, and an alkaline chemical liquid (e.g., SC 1) is supplied from the chemical liquid nozzle 71 B to the peripheral edge portion of the upper surface (device forming surface) of the wafer W so as to remove a contaminant on the peripheral edge portion of the upper surface of the wafer. At the same time, a chemical liquid, which is the same as the chemical liquid supplied from the chemical liquid nozzle 71B, is supplied from the processing liquid ejection port 22 for chemical liquid to the peripheral edge portion of the lower surface of the wafer W so as to remove a contaminant on the peripheral edge portion of the lower surface of the wafer W. When performing this second chemical liquid processing, the chemical liquid nozzle 71B may reciprocate in the radial direction of the wafer W similarly to when performing the first chemical processing in some embodiments. When the chemical liquid nozzle 71B reciprocates in the radial direction of the wafer W, it is possible to adjust the height of the gas supply nozzle 5 using the lifting mechanism 6 as described above, and to control the distance between the position at which the chemical liquid reaches the wafer W and the grounding position 523 of the air flow 101 (step S7 in FIG. 9).

### [Second Rinse Processing]

After performing the chemical processing for a predetermined time, the wafer W is continuously rotated in the clockwise direction (the rotation speed may be changed) and the N₂ gas is continuously ejected from the gas ejection ports 212 and 213. Then, while continuing rotation and ejection, the ejection of the chemical liquid from the chemical liquid nozzle 71B and the processing liquid ejection port 22 for chemical liquid is stopped, and the rinse liquid (DIW) is supplied from the rinse nozzle 72B and the processing liquid ejection port 22 for rinse liquid to the peripheral edge portion of the wafer W so as to perform the rinse processing. By this rinse processing, the chemical liquid, a reaction product, and the like remaining on the upper and lower surfaces of the wafer W are washed away (step S8 in FIG. 9).

### [Dry Processing]

After performing the second rinse processing for a predetermined time, the wafer W is continuously rotated in the clockwise direction (the rotation speed may be increase in some embodiments) and the N₂ gas is continuously ejected from the gas ejection ports 212 and 213. Then, while continuing the rotation and the ejection, the ejection of the rinse liquid from the rinse nozzle 72B and the processing liquid ejection port 22 for rinse liquid is stopped, and the drying gas (N₂ gas) is supplied from the gas nozzle 73B to the peripheral edge portion of the wafer W so as to perform dry processing. Thus, a series of processes for processing one wafer W is completed (step S9 in FIG. 9).

### [Disappearance of Air Curtain]

Next, the operation of the gas supply nozzle 5 is stopped so as to cause the air curtain to disappear (step S10 in FIG. 9).

### [Wafer Release and Unloading]

Thereafter, the gas supply nozzle 5 is raised and positioned at the retracted position, and the cup body 2 is lowered. Next, the shutter 12 of the housing 11 is opened, a transport arm (not illustrated) of an external wafer transport mechanism (not illustrated) enters the housing 11, and an empty transport arm is positioned below the wafer W held by the wafer holder 3. Subsequently, the empty transport arm is raised, and receives the wafer W from the wafer holder 3, which releases the wafer W by stopping the suction of the wafer W. Thereafter, the transport arm holding the wafer is retracted from the inside of the housing 11. Thus, a series of procedures in the liquid processing apparatus for one wafer is terminated (step S11 in FIG. 9). When there is a wafer W to be processed next (“Yes” in step S12 in FIG. 9), a series of steps (processing) from step S1 is performed on the next wafer W.

During the normal operation of the liquid processing apparatus 1, the clean air introduction unit 14 is always operating. In addition, as described above, during the normal operation of the liquid processing apparatus 1, the internal space of the cup body 2 is always sucked through the exhaust path 245, and the pressure in the inner recess 242 is maintained lower than the pressure in the housing 11 outside the cup body 2. Accordingly, during the normal operation of the liquid processing apparatus 1, gas (usually clean air) flows into the exhaust flow path 27 of the cup body 2 from above the cup body 2. In addition, when the wafer W is rotating, clean air near the upper surface of the wafer W flows toward the outside of the wafer W through the vicinity of the upper surface of the wafer W under the influence of the rotation of the wafer W, flows in a swirling manner, and flows into the exhaust flow path 27 of the cup body 2.

In addition to the gas flow on the upper surface side of the wafer W described above, the flow of N₂ gas flowing into the exhaust flow path 27 after flowing toward the outside of the wafer W along the lower surface of the wafer W from the gas ejection ports 212 and 213 is formed on the lower surface side of the wafer W.

During the execution of the first chemical liquid processing, the first rinse processing, the second chemical liquid processing, and the second rinse processing, the mist 99 of the chemical liquid or the rinse liquid ejected from the nozzles 71A, 71B, 72A, and 72B is formed as described above. In order to directly suppress the readhesion of the mist 99 to the upper surface of the wafer W, it is conceivable to provide a cover member. However, the mist 99 adhering to the cover member may fall on the wafer W, and particles may be formed. In contrast, in the present embodiment, by the gas ejection from the gas supply slit part 52, radially-outward air flow 104 is formed, as illustrated in FIG. 6, and the mist 99 entrained in the air flow 104 is carried to the exhaust flow path 27. Thus, according to the present embodiment, it is possible to remarkably reduce the readhesion of the mist 99 of the chemical liquid or the rinse liquid to the wafer W, and to reliably suppress the formation of particles.

The ejection direction of the processing fluid from each of the nozzles 71A to 73A and 71B to 73B is not particularly limited, but a direction, having a component in a direction oriented to the upper surface of the wafer W, a component in a same direction, which is the same as the rotation direction of the wafer W during processing, and a radially-outward component, may be set as the ejection direction in some embodiments. Thereby, it becomes easier to discharge the mist 99 to the exhaust flow path 27.

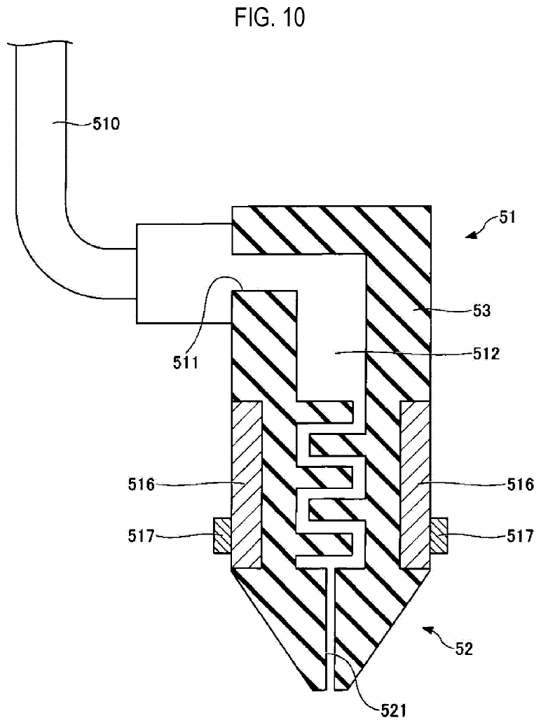

With respect to the structure of the slit part 52, in the example illustrated in FIG. 4, the heater 516 is provided in the ceramic housing 53, but the heater 516 may be mounted on the outer surface of the housing 53 as illustrated in FIG. 10.

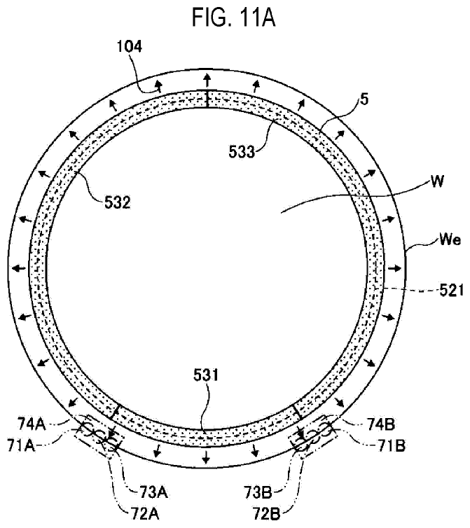

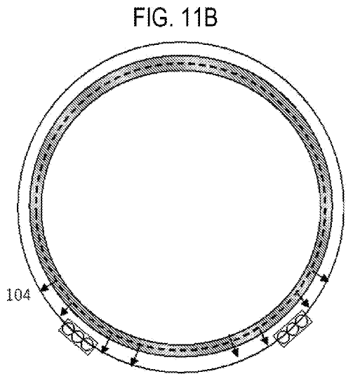

As illustrated in FIGS. 11A and 11B, the gas supply nozzle 5 is divided into multiple parts in the circumferential direction, and the flow rate or temperature of the gas ejected from the slit part 52 or both of them may be made different for each area obtained by the division. In the example illustrated in FIGS. 11A and 11B, the annular gas supply nozzle 5 is divided into a first area 531, which overlaps the shorter one of arcs bisected by the nozzle holders 74A and 74B, and a second area 532 and a third area 533, which are obtained by bisecting an area overlapping the longer one of the arcs. That is, the annular gas supply nozzle 5 is divided into three areas along the circumferential direction.

When making the gas flow rates different for respective areas, for example, the air buffer chamber 512 may be partitioned between adjacent areas, an independent air supply line may be provided in each region, and the opening degree of a flow rate adjustment valve may be independently controlled. The degree of scattering of the mist 99 is not uniform along the rotation direction of the wafer W, and more mist 99 is scattered in the area closer to the nozzle that ejects the chemical liquid and the rinse liquid. Accordingly, it is possible to efficiently discharge the mist 99 by increasing the gas flow rate in the area close to the nozzle and decreasing the gas flow rate in the area away from the nozzle.

In the case where the gas temperatures are made different for respective areas, for example, an independent heater 516 and an independent temperature sensor 517 may be provided in each area, and the temperature of the heater 516 may be controlled independently. The temperature of the peripheral edge portion Wp is not uniform in the rotation direction of the wafer W, and the temperature is more likely to decrease in an area closer to a nozzle that ejects the chemical liquid and the rinse liquid. Therefore, it is possible to efficiently control the temperature of the peripheral edge portion Wp by increasing the gas temperature in an area close to the nozzle and decreasing the gas temperature in an area away from the nozzle.

In addition, the number of parts obtained by dividing the gas supply nozzle 5 in the circumferential direction is not limited, and may be two, or may be four or more.

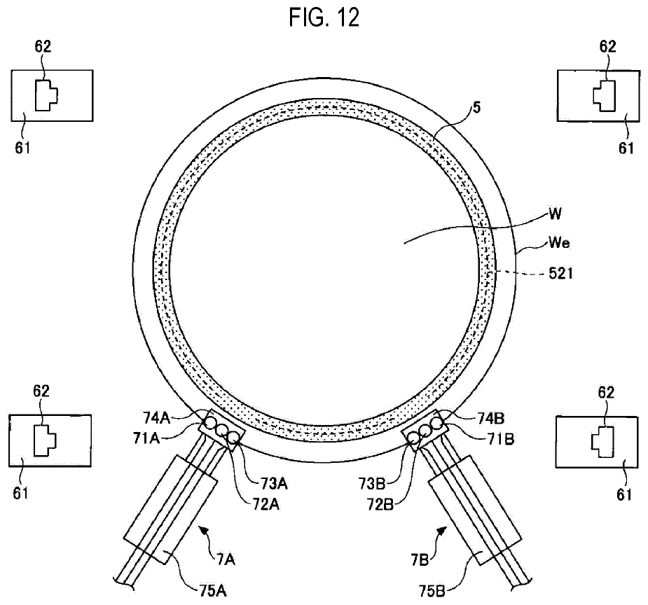

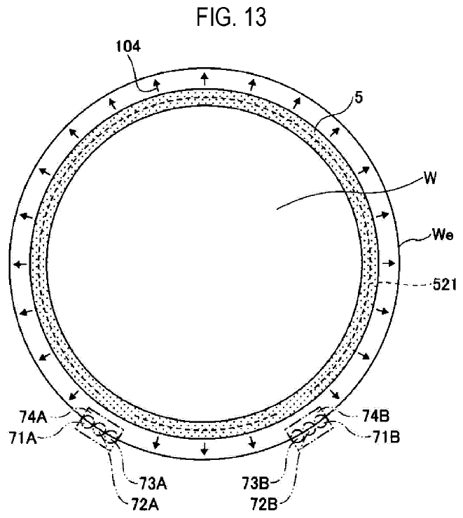

As illustrated in FIG. 12, a slit 521 may not be formed in the gas supply nozzle 5 in the vicinity of the nozzles 71A to 73A and 71B to 73B. In this case, as illustrated in FIG. 13, the air flow 104 on the upper surface of the peripheral edge portion Wp do not exist immediately below the nozzles 71A to 73A and 71B to 73B. If there is a concern that the chemical liquid or the rinse liquid ejected from the nozzles 71A, 72A, 71B, and 72B is affected by the air flow 104 before reaching the peripheral edge portion Wp, it is possible to suppress the influence of the air flow 104 by adopting this configuration. For example, even if the mist 99 falls onto the peripheral edge portion Wp from a portion where there is no air flow 104, since the wafer W is rotating at a high speed, the mist 99 is scattered radially outward by strong air flow 104 before formation particles. Accordingly, it is possible to suppress the formation of particles caused due to the adhesion of mist 99.

A second gas supply nozzle having a small diameter may be provided inside the gas supply nozzle 5 with the same configuration as the gas supply nozzle 5. The number of second gas supply nozzles may be one, or two or more. For example, it is possible to independently control the flow rate of the gas ejected from the gas supply nozzle 5 and the flow rate of the gas ejected from a second gas supply nozzle.

The liquid processing performed using the single liquid processing apparatus 1 is not limited to the above description. For example, the chemical liquid is not limited to the above-described HF and SC-2, and may be any known chemical liquid. In addition, one type of chemical liquid may be supplied to the wafer W. The substrate to be processed is not limited to a semiconductor wafer, and may be any of various circular substrates that require cleaning of the peripheral edge portion, such as a glass substrate or a ceramic substrate.

Embodiments have been described in detail above, but the present disclosure is not limited to the above-described embodiments and the like, and various modifications can be made to the above-described embodiments and the like without departing from the scope described in the claims.

According to the present disclosure, it is possible to more reliably suppress the formation of particles.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus comprising:
a substrate holding/rotating part configured to hold and rotate a substrate;
a processing liquid supply nozzle configured to supply a processing liquid to a peripheral edge portion of the substrate held by the substrate holding/rotating part; and
a gas supply nozzle provided inside the peripheral edge portion in a plan view and configured to supply a gas in an annular shape to a processing surface of the substrate to which the processing liquid is supplied,
wherein the gas supply nozzle is further configured to supply the gas from a direction perpendicular to the processing surface toward a direction inclined outward from a rotation center of the substrate.

2. The substrate processing apparatus of claim 1, wherein the gas supply nozzle is further configured to supply the gas in the annular shape or to a vicinity of the processing liquid supply nozzle from the direction perpendicular to the processing surface toward the direction inclined outward from the rotation center of the substrate.

3. The substrate processing apparatus of claim 2, wherein the gas supply nozzle is further configured to supply the gas inside a portion of the processing surface that is struck by the processing liquid supplied from the processing liquid supply nozzle.

4. The substrate processing apparatus of claim 2, further comprising:
a movement mechanism configured to adjust a height of the gas supply nozzle from the processing surface.

5. The substrate processing apparatus of claim 2, wherein the gas supply nozzle comprises a slit at a tip from which the gas is ejected.

6. The substrate processing apparatus of claim 2, wherein the gas supply nozzle comprises a heater configured to heat the gas that is ejected.

7. The substrate processing apparatus of claim 2, wherein the gas supply nozzle is divided into a plurality of areas in a circumferential direction, and is further configured to eject the gas under different conditions between the plurality of areas.

8. The substrate processing apparatus of claim 1, wherein the gas supply nozzle is further configured to supply the gas inside a portion of the processing surface that is hit by the processing liquid supplied from the processing liquid supply nozzle.

9. The substrate processing apparatus of claim 8, further comprising:
a movement mechanism configured to adjust a height of the gas supply nozzle from the processing surface.

10. The substrate processing apparatus of claim 8, wherein the gas supply nozzle comprises a slit at a tip from which the gas is ejected.

11. The substrate processing apparatus of claim 1, further comprising a movement mechanism configured to adjust a height of the gas supply nozzle from the processing surface.

12. The substrate processing apparatus of claim 11, wherein the gas supply nozzle comprises a heater configured to heat the gas that is ejected.

13. The substrate processing apparatus of claim 1, wherein the gas supply nozzle comprises a slit at a tip from which the gas is ejected.

14. The substrate processing apparatus of claim 1, wherein the gas supply nozzle comprises a heater configured to heat the gas that is ejected.

15. The substrate processing apparatus of claim 7, wherein the gas supply nozzle is configured to vary a flow rate of the ejected gas between the plurality of areas.

16. The substrate processing apparatus of claim 7, wherein the gas supply nozzle is configured to vary a temperature of the ejected gas between the plurality of areas.

17. The substrate processing apparatus of claim 1, wherein the gas supply nozzle is divided into a plurality of areas in a circumferential direction, and is further configured to eject the gas under different conditions between the plurality of areas.

18. The substrate processing apparatus of claim 1, further comprising:
a second gas supply nozzle provided inside the gas supply nozzle in the plan view and configured to supply a gas in an annular shape to the processing surface of the substrate to which the processing liquid is supplied,
wherein the second gas supply nozzle is further configured to supply the gas in the annular shape from the direction perpendicular to the processing surface toward the direction inclined outward from the rotation center of the substrate.

19. A substrate processing method comprising:
causing a substrate holding/rotating part to hold and rotate a substrate;
supplying a processing liquid from a processing liquid supply nozzle to a peripheral edge portion of the substrate held by the substrate holding/rotating part; and
supplying a gas in an annular shape from a gas supply nozzle provided inside the peripheral edge portion in a plan view to a processing surface of the substrate to which the processing liquid is supplied,
wherein, in supplying a gas, the gas is supplied in the annular shape from a direction perpendicular to the processing surface toward a direction inclined outward from a rotation center of the substrate.

20. The substrate processing method of claim 19, further comprising:
adjusting a position in the processing surface to which the gas is supplied by adjusting a height of the gas supply nozzle from an upper surface of the substrate.
